(19) United States
(12) Patent Application Publication
(10) Pub. No.: US 2024/0339359 A1
(43) Pub. Date: Oct. 10, 2024

(54) METHODS FOR DEPOSITING GAP-FILLING FLUIDS AND RELATED SYSTEMS AND DEVICES

(71) Applicant: ASM IP Holding B.V., Almere (NL)

(72) Inventors: René Henricus Jozef Vervuurt, Leuven (BE); Timothee Blanquart, Oud-Heverlee (BE); Jihee Jeon, Tempe, AZ (US); YongMin Yoo, Cheonan-si (KR); Andrey Sokolov, Seoul (KR); Maarten Stokhof, Winksele (BE); Steven Van Aerde, Tielt-Winge (BE); Dieter Pierreux, Pepingen (BE); Hussein Mehdi, Oud-Heverlee (BE)

(21) Appl. No.: 18/626,758

(22) Filed: Apr. 4, 2024

Related U.S. Application Data
(60) Provisional application No. 63/457,415, filed on Apr. 6, 2023.

(51) Int. Cl. H01L 21/768; H01L 21/02

(52) U.S. Cl. CPC H01L 21/76879; H01L 21/02126; H01L 21/0217; H01L 21/02274

(57) ABSTRACT

The present disclosure relates to method and apparatuses for filling a gap on a substrate. The method comprises providing a substrate, which comprises at least one gap into a reaction chamber, depositing a silicon containing first layer onto the substrate; subjecting the first layer to a phosphorous containing compound to form a flowable intermediate material, which at least partially fills the at least one gap on the substrate; and forming a solid material comprising silicon.

### CROSS-REFERENCE TO RELATED APPLICATIONS

The present application claims priority to and the benefit of U.S. Provisional Application No. 63/457,415, filed Apr. 6, 2023, the entirety of which is incorporated by reference herein.

### FIELD OF INVENTION

The present disclosure generally relates to methods and systems suitable for forming electronic devices. More particularly, the disclosure relates to methods and systems that can be used for depositing a material in gaps, trenches, and the like by plasma-assisted deposition.

### BACKGROUND OF THE DISCLOSURE

The scaling of semiconductor devices has led to significant improvements in speed and density of integrated circuits. However, with miniaturization of wiring pitch of large scale integration devices, void-free filling of high aspect ratio trenches (e.g., trenches having an aspect ratio of three or higher) becomes increasingly difficult due to limitations of existing deposition processes. Therefore, there remains a need for processes that efficiently fill high aspect ratio features, e.g., gaps such as trenches on semiconductor substrates

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior art.

### SUMMARY OF THE DISCLOSURE

Various embodiments of the present disclosure relate to gap filling methods, to structures and devices formed using such methods, and to apparatus for performing the methods and/or for forming the structure and/or devices. The ways in which various embodiments of the present disclosure address drawbacks of prior methods and systems are discussed in more detail below.

Further described is a method for filling a gap in a substrate. The method comprises providing a substrate into a reaction chamber, wherein the substrate comprises at least one gap; forming a first layer on a substrate, wherein the first layer comprises silicon and nitrogen; subjecting the first layer to a phosphorous containing compound to form a flowable intermediate material at least partially filling the at least one gap on the substrate, wherein the intermediate material comprises silicon, oxygen and hydrogen; and forming a solid material comprising silicon.

In some embodiments the step of subjecting the first layer to a phosphorous containing compound additionally comprises subjecting the first layer to moisture.

In some embodiments the moisture is selected from the group consisting of H₂O, steam or H₂O₂.

In some embodiments, the solid material comprises silicon dioxide.

In some embodiments, the phosphorous containing compound comprises phosphorous at an amount so that the first layer comprises at least 4 atomic-% phosphorous after it has been subjected to the phosphorous containing compound.

In some embodiments the step of forming a first layer comprises executing a plurality of deposition cycles to form a silicon-containing layer. A deposition cycle comprises a silicon precursor pulse that comprises exposing the substrate to a silicon precursor; and a plasma pulse that comprises exposing the substrate to a plasma treatment, wherein the plasma treatment comprises generating plasma.

In some embodiments, subsequent deposition cycles are separated by a purge.

In some embodiments, the precursor pulse and the plasma pulse at least partially overlap.

In some embodiments the plasma is a direct plasma. In some embodiments the plasma is a remote plasma. In some embodiments the plasma is an indirect plasma.

In some embodiments, the plasma is generated using plasma gas, the plasma gas comprising N₂ and optionally one or more noble gases.

In some embodiments, the noble gas comprises one or more of He and Ar.

In some embodiments, the silicon precursor comprises silicon and optionally phosphorous.

In some embodiments, the method comprises one or more super cycles, a super cycle comprising a step of forming a first layer on a substrate, subjecting the first layer to a phosphorous containing compound and forming a solid material comprising silicon.

Further described herein is a semiconductor processing apparatus. The apparatus comprises a reaction chamber comprising a substrate support for supporting a substrate; a heater constructed and arranged to heat the substrate in the reaction chamber; a plasma module comprising a radio frequency power source constructed and arranged to generate a plasma; a plasma gas source in fluid communication with the plasma module; a silicon precursor source in fluid connection with the reaction chamber via one or more precursor valves; and, a controller configured for causing the semiconductor processing apparatus to perform a method according to the method described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 shows a schematic representation of an embodiment of a method described herein.

FIG. 2 shows a schematic representation of an embodiment of a method described herein.

FIG. 3 shows a schematic representation of an embodiment of a method described herein.

FIG. 4 illustrates a deposition assembly 400 according to the current disclosure in a schematic manner.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. Exemplary gasses can include precursors and reactants.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said wording. When the term “consisting” is used referring to a chemical compound or substance, it indicates that the chemical compound only contains the components which are listed.

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components that are listed.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

It shall be understood that terms like “depositing” and the like, as used herein, can refer to a phase change from the gas phase to a solid phase change, through an intermediate flowable phase. Indeed, the meaning of the term “depositing” can include phase changes from a gaseous phase to a liquid phase, and can include processes in which gaseous reactants form liquid, liquid-like, or solidifying fluids. Thus, the meaning of the term “depositing” can encompass similar terms like condensing or forming.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate.

A film or layer may comprise material or a layer with pinholes and/or isolated islands. A film or layer may be at least partially continuous. A film or layer may be patterned, e.g., subdivided, and may be comprised in a plurality of semiconductor devices.

As used herein, a “structure” can be or include a substrate as described herein. Structures can include one or more layers overlying the substrate, such as one or more layers formed according to a method as described herein. Device portions and interconnects can be or include structures.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential exposure of a substrate to precursors (and/or reactants) into a reaction chamber, and exposure of a substrate to plasma generated species to deposit a layer over the substrate, and includes processing techniques such as plasma-enhanced atomic layer deposition (PEALD).

Generally, for PEALD processes, during each cycle, a precursor is introduced to a reaction chamber and is chemisorbed to a deposition surface (e.g., a substrate surface that can include a previously deposited material from a previous PEALD cycle or other material) and forms about a monolayer or sub-monolayer of material that does not readily react with additional precursor (i.e., a self-limiting reaction). Thereafter, the substrate is exposed to a plasma-generated species which can be generated using any plasma, such as a direct, indirect, or remote plasma. Plasmas can be generated capacitively, inductively, using microwave radiation, or through other means. The plasma-generated species converts the chemisorbed precursor to the desired material on the deposition surface. Purging steps can be utilized during one or more cycles, e.g., after each step or pulse of each cycle, to remove any excess precursor from the process chamber and/or remove any excess plasma-generated species and/or reaction byproducts from the reaction chamber.

As used herein, the term “purge” may refer to a procedure in which a purge gas is provided to a reaction chamber in between a precursor pulse and a plasma pulse. It shall be understood that during a purge, the substrate is not exposed to plasma-generated species. For example, when a direct plasma is used, the plasma can be turned off during a purge. For example, a purge, e.g., using a purge gas such as nitrogen or a noble gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used e.g., in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

In some embodiments, the term “gap filling fluid”, also referred to as “flowable gap fill” or “flowable intermediate material”, may refer to an oligomer which is liquid under the conditions under which it is deposited on a substrate and which has the capability to cross link, and for a solid film.

In some embodiments, the term “filling capability” may refer to a capability of filling a gap substantially without voids (e.g., no void having a size of approximately 5 nm or greater in diameter) and seams (e.g. no seam having a length of approximately 5 nm or greater), wherein seamless/void-less bottom-up growth of a layer is observed. In some embodiments, the growth at a bottom of a gap may be at least approximately 1.5 times faster than growth on sidewalls of the gap and on a top surface having the gap. A film having filling capability can be referred to as “flowable film” or “viscous film”. The flowable or viscous behavior of a film is often manifested as a concave surface at a bottom of a trench.

In this disclosure, a recess between adjacent protruding structures and any other recess pattern may be referred to as a “trench” or “gap”. That is, a trench or gap may refer to any recess pattern including a hole/via. A trench or gap can have, in some embodiments, a width of about 5 nm to about 150 nm, or about 30 nm to about 50 nm, or about 5 nm to about 10 nm, or about 10 nm to about 20 nm, or about 20 nm to about 30 nm, or about 50 nm to about 100 nm, or about 100 nm to about 150 nm. When a trench or gap has a length that is substantially the same as its width, it can be referred to as a hole or a via. Holes or vias typically have a width of about 20 nm to about 100 nm. In some embodiments, a trench has a depth of about 30 nm to about 100 nm, and typically of about 40 nm to about 60 nm. In some embodiments, a trench or gap has an aspect ratio of about 2 to about 10, and typically of about 2 to about 5. The dimensions of the trench or gap may vary depending on process conditions, film composition, intended application, etc.

Described herein is a method for filling a gap in a substrate. A gap in a substrate may refer to a patterned recess or trench in a substrate. The gap filling method can be used during manufacturing processes of various semiconductor devices including, but not limited to, cell isolation in 3D cross point memory devices, self-aligned via, dummy gate, reverse tone patterning, PC RAM isolation, cut hard mask and DRAM storage node contact isolation.

In particular, the presently described method comprises providing a substrate into a reaction chamber. The substrate comprises at least one gap. The method further comprises forming a first layer on a substrate, wherein the first layer comprises silicon and nitrogen; subjecting the first layer to a phosphorous containing compound to form a flowable intermediate material at least partially filling the at least one gap on the substrate, wherein the intermediate material comprises silicon, oxygen and hydrogen; and forming a solid material comprising silicon.

In some embodiments, the method includes entirely filling the gap with a flowable intermediate material. In some embodiments, the method includes filling the gap with flowable intermediate material without the formation of voids or seams. In other words, in some embodiments, the process according to the present methods is continued until the gap is fully filled with a material having filling capability, and substantially no voids or seams are formed in the filled gap. The presence of voids or seams can be observed by studying the formed material in a scanning tunneling electron microscope.

In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10000 nm, or of at least 20 nm to at most 5000 nm, or from at least 40 nm to at most 2500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10000 nm, or of at least 20 nm to at most 5 000 nm, or from at least 40 nm to at most 2500 nm, or from at least 80 nm to at most 1000 nm, or from at least 100 nm to at most 500 nm, or from at least 150 nm to at most 400 nm, or from at least 200 nm to at most 300 nm. In some embodiments, the flowable intermediate material extends into a particular gap for a distance that equals from at least 1.0 to at most 10.0 times the width of the gap. In some embodiments, the flowable intermediate material extends into a particular gap for a distance that equals from at least 1.5 to at most 9.0 times the width of the gap. In some embodiments, the flowable intermediate material extends into a particular gap for a distance that equals from at least 2.0 to at most 8.0 times the width of the gap. In some embodiments, the flowable intermediate material extends into a particular gap for a distance that equals from at least 3.0 to at most 6.0 times the width of the gap. In some embodiments, the flowable intermediate material extends into a particular gap for a distance that equals from at least 4.0 to at most 6.0 times the width of the gap. In some embodiments, the flowable intermediate material extends into a particular gap for a distance that equals about 5.0 times the width of the gap. In other words, and in some embodiments, the flowable intermediate material fills the gap up to any one of the aforementioned distances from the bottom of the gap.

In some embodiments the step of subjecting the first layer to a phosphorous containing compound additionally comprises subjecting the first layer to moisture. In the current disclosure the term “moisture” is the presence of water or other liquid diffused as vapor or condensed on a surface. In some embodiments, the moisture comprises a water molecule, in other words H⁺HO⁻. In some embodiments the moisture is selected from the group consisting of H₂O, steam and H₂O₂.

In some embodiments, the first layer further comprises oxygen. In some embodiments, the phosphorous containing compound further contains oxygen. In some embodiments, the first layer further comprises the phosphorous containing compound. In some embodiments, flowable intermediate material is obtained when the first layer is subjected to a phosphorous containing compound and an oxygen and hydrogen containing compound and the material is polymerized. The oxygen and hydrogen containing compound may be present in the first layer itself, in the phosphorous containing compound or alternatively in the subjected moisture. As a result, the first layer that is subjected to a phosphorous containing compound and oxygen hydrogen containing compound, reacts to form a flowable intermediate material comprising silicon, hydrogen and oxygen.

The solid material is the material that has flowed into the gap at least partially filling it. In some embodiments, the solid material comprises silicon dioxide. In some embodiments, the solid material comprises silicon nitride. In some embodiments, the solid material comprises silicon oxynitride.

In some embodiments, the phosphorous containing compound comprises phosphorous at an amount so that a first layer comprises at least 2 atomic-% phosphorous after it has been subjected to the phosphorous containing compound. In some embodiments, the phosphorous containing compound comprises phosphorous at an amount so that the first layer comprises at least 4 atomic-% phosphorous after it has been subjected to the phosphorous containing compound. In some embodiments, the phosphorous containing compound comprises phosphorous at an amount so that the first layer comprises at least 6 atomic-% phosphorous after it has been subjected to the phosphorous containing compound. In some embodiments, the phosphorous containing compound comprises phosphorous at an amount so that the first layer comprises at least 8 atomic-% phosphorous after it has been subjected to the phosphorous containing compound. In some embodiments, the phosphorous containing compound comprises phosphorous at an amount so that the first layer comprises less than 12 atomic-% phosphorous after it has been subjected to the phosphorous containing compound. In some embodiments, the phosphorous containing compound comprises phosphorous at an amount so that the first layer comprises less than 10 atomic-% phosphorous after it has been subjected to the phosphorous containing compound.

In some embodiments the step of forming a first layer comprises executing a plurality of deposition cycles to form a silicon-containing layer. A deposition cycle comprises a silicon precursor pulse that comprises exposing the substrate to a silicon precursor; and a plasma pulse that comprises exposing the substrate to a plasma treatment, wherein the plasma treatment comprises generating plasma.

In some embodiments, the first layer comprises silicon and nitrogen. In some embodiments, the first layer comprises silicon nitride. In some embodiments, the first layer comprises silicon, nitrogen and phosphorous.

In some embodiments, the step of forming a first layer further comprises a phosphorous precursor pulse that comprises exposing the substrate to a phosphorous precursor.

In some embodiments, subsequent deposition cycles are separated by a purge.

In some embodiments, the precursor pulse and the plasma pulse at least partially overlap. In other words, and in some embodiments, the precursor pulse and the plasma pulse occur at least partially simultaneously. In such embodiments, the cyclical deposition process does not contain an intra-cycle purge. In some embodiments, the cyclical deposition process does not contain an inter-cycle purge.

In some embodiments the plasma is a direct plasma. In some embodiments the plasma is a remote plasma. In some embodiments the plasma is an indirect plasma.

In some embodiments, the plasma is generated using plasma gas, the plasma gas comprising N₂ and optionally one or more noble gases. In some embodiments, the noble gas comprises one or more of He and Ar.

In some embodiments, the plasma gas is continuously provided into the reaction chamber. In some embodiments, the plasma gas is supplied to the reaction chamber as a carrier gas, i.e., as a gas that entrains the precursor, and/or as an additional gas. In some embodiments, the carrier gas is provided at a flow rate of at least 0.2 to at most 6.0 slpm, or from at least 0.3 to at most 4 slpm, or from at least 0.4 to at most 2 slpm, or from at least 0.5 to at most 1 slpm.

In some embodiments, the plasma pulses comprise generating an RF plasma in the reaction chamber. In some embodiments, a plasma power of at least 10 W to at most 2000 W is used during the plasma pulses. In some embodiments, a plasma power of at least 100 W to at most 1500 W is used during the plasma pulses. In some embodiments, a plasma power of at least 300 W to at most 1000 W is used during the plasma pulses.

In some embodiments, the method is executed in a system comprising two electrodes between which the substrate is positioned. The electrodes are positioned parallel at a pre-determined distance called an electrode gap. In some embodiments, the electrode gap is at least 5 mm to at most 30 mm, at least 5 mm to at most 10 mm, or at least 10 mm to at most 20 mm, or of at least 20 mm to at most 30 mm.

In some embodiments, a plasma frequency of at least 40 kHz to at most 2.45 GHz is used during the plasma pulses, or a plasma frequency of at least 40 kHz to at most 80 kHz is used during the plasma pulses, or a plasma frequency of at least 80 kHz to at most 160 kHz is used during the plasma pulses, or a plasma frequency of at least 160 kHz to at most 320 kHz is used during the plasma pulses, or a plasma frequency of at least 320 kHz to at most 640 kHz is used during the plasma pulses, or a plasma frequency of at least 640 kHz to at most 1280 kHz is used during the plasma pulses, or a plasma frequency of at least 1280 kHz to at most 2500 kHz is used during the plasma pulses, or a plasma frequency of at least 2.5 MHz to at least 5 MHz is used during the plasma pulses, or a plasma frequency of at least 5 MHz to at most 50 MHz is used during the plasma pulses, or a plasma frequency of at least 5 MHz to at most 10 MHz is used during the plasma pulses, or a plasma frequency of at least 10 MHz to at most 20 MHz is used during the plasma pulses, or a plasma frequency of at least 20 MHz to at most 30 MHz is used during the plasma pulses, or a plasma frequency of at least 30 MHz to at most 40 MHz is used during the plasma pulses, or a plasma frequency of at least 40 MHz to at most 50 MHz is used during the plasma pulses, or a plasma frequency of at least 50 MHz to at most 100 MHz is used during the plasma pulses, or a plasma frequency of at least 100 MHz to at most 200 MHz is used during the plasma pulses, or a plasma frequency of at least 200 MHz to at most 500 MHz is used during the plasma pulses, or a plasma frequency of at least 500 MHz to at most 1000 MHz is used during the plasma pulses, or a plasma frequency of at least 1 GHz to at most 2.45 GHz is used during the plasma pulses. In exemplary embodiments, the plasma is an RF plasma, and RF power is provided at a frequency of 13.56 MHz.

In some embodiments, no gasses other than the silicon precursor and the plasma gas are introduced into the reaction chamber during the silicon precursor pulse and during the plasma pulse. Additionally or alternatively, and in some embodiments, no gasses other than the nitrogen gas and optionally noble gas are introduced into the reaction chamber during at least one of the intra-cycle purge and the inter-cycle purge.

In some embodiments, the present methods comprise providing the precursor intermittently to the reaction space, and continuously applying a plasma. Thus, in some embodiments, a continuous plasma is used instead of plasma pulses. In some embodiments, the present methods involve providing the precursor intermittently to the reaction space, and intermittently applying a plasma. Thus, in some embodiments, silicon precursor is continuously provided to the reaction chamber whereas a plasma is generated intermittently.

In some embodiments, a pulsed plasma, e.g., a pulsed RF plasma is generated in the reaction chamber. Thus, the method comprises a plurality of cycles, a cycle comprising a plasma on pulse and a plasma off pulse. In some embodiments, a plasma on pulse lasts from at least 0.7 seconds to at most 7.0 seconds, for example from at least 0.7 seconds to at most 1.5 seconds. In some embodiments, a plasma off pulse lasts from at least 0.7 seconds to at most 2.0 seconds, for example from at least 0.7 seconds to at most 1.5 seconds.

In some embodiments, the duration of the precursor pulse, i.e., the precursor feed time, is from at least 0.25 s to at most 4.0 s, or from at least 0.5 s to at most 2.0 s, or from at least 1.0 s to at most 1.5 s.

In some embodiments, the duration of the purge is from at least 0.025 s to at most 2.0 s, or from at least 0.05 s to at most 0.8 s, or from at least 0.1 s to at most 0.4 s, or from at least 0.2 s to at most 0.3 s.

In some embodiments, the silicon precursor comprises silicon. In some embodiments, the silicon precursor additionally comprises phosphorous. It shall be understood that, when the silicon precursor consists of certain components, other components may, in some embodiments, still be present in small quantities, e.g. as contaminants.

In some embodiments, the method comprises one or more super cycles, a super cycle comprising a step of forming a first layer a first layer on a substrate, subjecting the first layer to a phosphorous containing compound and forming a solid material comprising silicon.

In some embodiments, the method for filling a gap comprises from at least 10 to at most 30000 super cycles, or from at least 10 to at most 3000 super cycles, or from at least 10 to at most 1000 super cycles, or from at least 10 to at most 500 super cycles, or from at least 20 to at most 200 super cycles, or from at least 50 to at most 150 super cycles, or from at least 75 to at most 125 super cycles, for example 100 super cycles.

In some embodiments, the gap is entirely filled with the flowable intermediate material. It shall be understood that the flowable intermediate material can be described as a viscous material, i.e. a viscous phase that is deposited on the substrate. The flowable intermediate material is capable of flowing in a trench on the substrate. Suitable substrates include silicon wafers. As a result, the viscous material seamlessly fills the trench in a bottom-up way.

In some embodiments, the present methods are executed at a temperature of at least-25° C. to at most 800° C. In some embodiments, the present methods are executed at a temperature of at least −25° C. to at most 0° C. In some embodiments, the present methods are executed at a temperature of at least 0° C. to at most 25° C. In some embodiments, the present methods are executed at a temperature of at least 25° C. to at most 50° C. In some embodiments, the present methods are executed at a temperature of at least 50° C. to at most 75° C. In some embodiments, the present methods are executed at a temperature of at least 150° C. to at most 400° C. In some embodiments, the present methods are executed at a temperature of at least 400° C. to at most 700° C. This enhances the gap filling properties of the presently provided flowable intermediate material. In some embodiments, the reaction chamber is at a temperature of at least 70° C. to at most 90° C.

In some embodiments, the reaction chamber is maintained at a pressure of at least 600 Pa to at most 10000 Pa. For example, the pressure in the reaction chamber may be maintained at a pressure of at least 600 Pa to at most 1200 Pa, or at a pressure of at least 1200 Pa to at most 2500 Pa, or at a pressure of at least 2500 Pa to at most 5000 Pa, or at a pressure of at least 5000 Pa to at most 10000 Pa.

In some embodiments, the present methods are executed at a pressure of at least 500 Pa, preferably at a pressure of at least 700 Pa. More preferably, the present methods are executed at a pressure of at least 900 Pa. This enhances the gap filling properties of the presently provided flowable intermediate material.

In some embodiments, the reaction chamber is maintained at a pressure of at least 500 Pa to at most 1500 Pa, and the reaction chamber is maintained at a temperature of at least 50° C. to at most 150° C. In some embodiments, the present methods are executed at a pressure of at least 500 Pa to at most 10 000 Pa and at a temperature of at least 50° C. to at most 200° C. In some embodiments, the present methods are executed at a pressure of at least 700 Pa and at a temperature of at least 50° C. to at most 150° C. In some embodiments, the present methods are executed at a pressure of at least 900 Pa, and at a temperature of at least 50° C. to at most 75° C. In some embodiments, the present methods are executed at a pressure of about 1 atm and at temperature of at least 50° C. to at most 150° C.

In accordance with exemplary embodiments, when the filling the gap step is complete, the flowable film is no longer flowable but is solidified, and thus, a separate solidification process is not required. In other embodiments, the flowable film is densified and/or solidified after filling the gap. Densifying and/or solidifying the flowable film can be done by means of a curing step (also called “cure”).

Accordingly, in some embodiments, the method includes a step of curing the flowable intermediate material. This step increases the thermal resistance of the flowable intermediate material. In other words, it increases the resistance of the flowable intermediate material against deformation and/or mass loss at elevated temperatures. Additionally or alternatively, the curing step may cause the flowable intermediate material to solidify.

In some embodiments, the flowable intermediate material is cured after it has filled the gap. Optionally, the flowable intermediate material is subjected to an anneal after the flowable intermediate material has filled the gap and before the curing step. Suitable annealing times include from at least 10.0 seconds to at most 10.0 minutes, for example from at least 20.0 seconds to at most 5.0 minutes, for example from at least 40.0 seconds to at most 2.5 minutes. In some embodiments, the annealing times include from at least 20 minutes to at most 60 minutes. Suitably, the anneal is performed in a gas mixture comprising one or more gasses selected from the list consisting of N₂, He, Ar, and H₂. In some embodiments, the anneal is carried out at a temperature of at least 200° C., or at a temperature of at least 250° C., or at a temperature of at least 300° C., or at a temperature of at least 350° C., or at a temperature of at least 400° C., or at a temperature of at least 450° C. In some embodiments, the anneal is carried out at a temperature of at least 600° C. to at most 800° C.

In some embodiments, the flowable intermediate material may be cured while filling the gap, e.g., by cyclically alternating filling the gap and curing pulses. Thus, in some embodiments, a method as described herein comprises one or more super cycles. A super cycle comprises a step of executing the step of filling the gap and a curing step. When the super cycle is repeated several times, a cyclical process results. When the presently disclosed methods comprise only one super cycle, a process results in which flowable intermediate material first fills the gap, and is cured thereafter.

In some embodiments, a curing step comprises generating a plasma in the reaction chamber, thus exposing the substrate to a direct plasma. Suitable direct plasmas comprise noble gas plasmas. When a direct plasma is used, a thin layer of flowable intermediate material may be efficiently cured, yielding a thin high-quality layer. In some embodiments, especially when a thicker layer of cured flowable intermediate material is desired, the method for filling a gap may comprise a plurality of cycles in which steps of filling the gap with flowable intermediate material and curing steps employing a direct plasma treatment are alternated. In such embodiments, the process of filling a gap preferably comprises a plurality of cycles of steps for filling the gap and plasma treatment steps, also called pulses, are alternated. Such a cyclic process has the advantage that a larger portion of the flowable intermediate material is cured: a direct plasma can have a penetration depth of around 2 to 7 nm, such that a post deposition direct plasma treatment would only cure a top layer of the flowable intermediate material. Conversely, alternating filling the gap steps and plasma steps allows curing a larger part, or even the entirety of the flowable intermediate material, even when using a curing technique that can have a low penetration depth, such as a direct plasma.

Suitable plasma treatments include a H₂ plasma, an O₂ plasma, a He plasma, a H₂/He plasma, an Ar plasma, an Ar/O₂. He/O₂, N₂/O₂, an Ar/H₂ plasma, and an Ar/He/H₂ plasma. It shall be understood that a H₂ plasma refers to a plasma that employs H₂ as a plasma gas. Also, it shall be understood that a H₂/He plasma refers to a plasma that employs a mixture of H₂ and He as a plasma gas. It shall be understood that other plasmas are defined analogously.

In some embodiments, a curing step comprises providing a remote plasma, e.g., a remote noble gas plasma, and exposing the substrate to one or more excited species such as at least one of radicals, ions, and UV radiation. In some embodiments, the step of curing comprises the use of an indirect plasma after the gap has been filled with the flowable intermediate material. An indirect plasma can have a larger penetration depth than a direct plasma, thereby obviating the need for cyclic gap filling steps and curing steps. Thus, an indirect plasma cure may be applied as a post-gap filling step.

In some embodiments, the step of curing comprises providing a remote plasma source, and positioning one or more mesh plates between the remote plasma source and the substrate. Thus, the substrate can be exposed to radicals generated by the remote plasma source. The radicals have a penetration depth which is significantly higher than the penetration length offered by direct plasmas, e.g., significantly higher than the size of the gaps to be filled by means of the presently provided methods. Consequently, a remote plasma treatment may be advantageously applied once after all the flowable intermediate material has been formed. This notwithstanding, a remote plasma cure may also be applied cyclically with alternating plasma cure and flowable intermediate material forming steps, similar to the operation with a direct plasma. The large penetration depths of remote plasmas have the advantage that they allow efficient curing of flowable intermediate material. In some embodiments, the plasma gas employed in a remote plasma comprises a noble gas, for example a noble gas selected from the list consisting of He and Ar.

The step of curing may reduce the hydrogen concentration of the flowable intermediate materials with respect to their uncured state. For example, the hydrogen concentration is reduced by at least 0.01 atomic percent to at most 0.1 atomic percent, or by at least 0.1 atomic percent to at most 0.2 atomic percent, or by at least 0.2 atomic percent to at most 0.5 atomic percent, or by at least 0.5 atomic percent to at most 1.0 atomic percent, or by at least 1.0 atomic percent to at most 2.0 atomic percent, or by at least 2.0 atomic percent to at most 5.0 atomic percent, or by at least 5.0 atomic percent to at most 10.0 atomic percent.

In some embodiments, the step of curing comprises exposing the flowable intermediate material to a micro pulsed plasma. The application of a micro-pulsed plasma can be particularly advantageous since the formed flowable intermediate material comprises hydrogen. A micro pulsed plasma is a plasma treatment that comprises the application of a plurality of rapidly succeeding on-off micro pulses. The micro pulsed plasma may, for example, employ a noble gas as a plasma gas. When a 300 mm wafer is used as a substrate, a plasma gas flow rate of, for example, at least 5.0 slm, or of at least 5.0 slm to at most 7.0 slm, or of at least 7.0 slm to at most 10.0 slm is maintained during the micro pulsed plasma. For example, the on micro pulses in a micro pulsed plasma may last from at least 1.0 us to at most 1.0 s, or from at least 2.0 us to at most 0.50 s, or from at least 5.0 us to at most 250.0 ms, or from at least 10.0 us to at most 100.0 ms, or from at least 25.0 us to at most 50.0 ms, or from at least 50.0 us to at most 25.0 ms, or from at least 100.0 us to at most 10.0 ms, or from at least 250.0 us to at most 5.0 ms, or from at least 0.50 ms to at most 2.5 ms. For example, the off micro pulses in a micro pulsed plasma may last from at least 1.0 us to at most 2.0 s, or from at least 2.0 us to at most 1.0 s, or from at least 5.0 us to at most 500 ms, or from at least 10.0 us to at most 250.0 ms, or from at least 25.0 us to at most 100.0 ms, or from at least 50.0 us to at most 50.0 ms, or from at least 100.0 us to at most 25.0 ms, or from at least 200.0 us to at most 10.0 ms, or from at least 500.0 us to at most 5.0 ms, or from at least 1.0 ms to at most 2.0 ms. A micro pulsed plasma may be used cyclically, i.e. as a plasma pulse in a cyclical deposition treatment, and/or as a post-deposition treatment. In other words, a process of filling a gap may comprise alternating cycles of flowable intermediate material formation and micro pulsed plasma. Additionally or alternatively, the substrate may be subjected to a micro pulsed plasma post-deposition treatment after all flowable intermediate material has been formed.

In some embodiments, the substrate is subjected to a micro pulsed plasma while a plasma gas is provided to the reaction chamber at a flow rate that is higher than a pre-determined threshold. The combination of a micro pulsed plasma with these high flow rates minimizes redeposition of volatile by products released during plasma-induced cross linking of the formed flowable intermediate material. In some embodiments, the flow rate of the plasma gas during micro pulsed plasma treatment is at least 5.0 slm (standard liter per minute), preferably at least 10.0 slm. The skilled artisan understands that this flow rate depends on reaction chamber volume and substrate size, and the values provided here for 300 mm wafers and a reaction chamber volume of 1 liter can be readily transferred to other substrate sizes and/or reactor volumes. In some embodiments, a noble gas is used as a plasma gas during micro pulsed plasma treatment. In some embodiments, the noble gas is selected from the list consisting of He and Ar.

In some embodiments, the step of curing involves the use of ultraviolet (UV) light. In other words, the step of curing may involve exposing the substrate, including the flowable intermediate material, to UV radiation. Such a curing step employing UV light may be called a UV cure.

In some embodiments, a UV cure is used as a post-deposition treatment. In other words, in some embodiments, the present methods can comprise forming a flowable intermediate material, and subjecting the flowable intermediate material to a UV cure.

In some embodiments, the present methods comprise a cyclic process comprising a plurality of cycles, the cycles each comprising a flowable intermediate material formation step and a UV curing step. The UV curing step may be separated by a purge step. Additionally or alternatively, subsequent cycles may be separated by a purge step. Suitable purge steps are described elsewhere herein.

In an exemplary embodiment, an exemplary curing step is discussed. The curing step may employ a continuous direct plasma for between 10 seconds and 10 minutes. Flowable intermediate material formation steps and direct plasma curing steps may be carried out cyclically, i.e., flowable intermediate material formation steps and curing steps may be executed alternatingly. This allows efficiently curing all, or at least a large portion, of the flowable intermediate material. For curing flowable intermediate material in gaps on a 300 mm substrate, each direct plasma curing step can feature, for example, 10 seconds to 10 minutes of Ar/O₂ plasma (having 20 w-% O₂ in the gas mixture) at an RF power of 200 to 600 W and a working pressure of 400 to 800 Pa. The reactor volume is ca. 1 liter and the Ar/O₂ flow rate is 2 slm.

According to one embodiment, the method further comprises an anneal step wherein the solid material is exposed to heating to a temperature between 200° C. and 700° C. In some embodiments, the anneal step comprises heating the solid material to a temperature between 500° C. and 700° C. In some embodiments, the anneal step further comprises exposing the solid material to moisture. In some embodiments, the moisture is water steam. In some embodiments, the anneal step lasts 20 to 60 minutes. In some embodiments, the anneal step is performed in a N₂ atmosphere.

According to one embodiment, wherein the forming a first layer further comprises a second plasma pulse that comprises exposing the substrate to a plasma treatment, wherein the plasma treatment comprises generating plasma. In some embodiments, the plasma is generated using plasma gas, the plasma gas comprising a gas selected from the list consisting of NH₃, H₂, a mixture of H₂ and N₂, a mixture of H₂ and He, a mixture of H₂ and argon and N₂H₂. The second plasma pulse decreases the phosphorous impurity in the deposited layer. In some embodiments, the phosphorous impurity is less than 3%, in some embodiments, the phosphorous impurity is less than 2%.

According to one embodiment, wherein before forming a first layer on a substrate, a liner layer is deposited into the gap. In some embodiments, the liner comprises silicon oxynitride further comprising a low amount of impurity phosphorous, such as under 2.5% of phosphorous. In some embodiments, the liner comprises silicon nitride further comprising a low amount of impurity phosphorous, such as under 2.5% of phosphorous. In some embodiments, the silicon nitride or silicon oxynitride layer does not contain any phosphorous. According to one embodiment, the method for filling a gap does not comprise a plasma step. In other words, the step of forming a first layer on a substrate is performed with a thermal deposition process without the need of plasma.

Further described herein is a semiconductor processing apparatus. The apparatus comprises a reaction chamber, a radio frequency power source, a gas injection system, a precursor gas source, a plasma gas source, an exhaust, and a controller. The reaction chamber comprises a substrate support and an upper electrode. The substrate support comprises a lower electrode. The radio frequency power source is arranged for generating a radio frequency power waveform. The gas injection system is in fluid connection with the reaction chamber. The precursor gas source is arranged for introducing a silicon precursor into the reaction chamber. Optionally, the silicon precursor is introduced in the reaction chamber by means of a carrier gas. The plasma gas source is arranged for introducing a reactant in the reaction chamber. The exhaust is suitably arranged for removing reaction products and unused reactants from the reaction chamber. The controller is programmed or otherwise configured to cause the methods described elsewhere herein to be conducted. The controller(s) communicate with the various power sources, heating systems, pumps, robotics, and gas flow controllers or valves of the system, as will be appreciated by the skilled artisan.

In some embodiments, the precursor source that comprises a precursor recipient, e.g. a precursor canister, a precursor bottle, or the like; and one or more gas lines operationally connecting the precursor recipient to the reaction chamber. In such embodiments, the precursor recipient may be suitably maintained at a temperature which is from at least 5° C. to at most 50° C. lower than the temperature of the reaction chamber, or at a temperature which is from at least 5° C. to at most 10° C. lower than the temperature of the reaction chamber, or at a temperature which is from at least 10° C. to at most 20° C. lower than the temperature of the reaction chamber, or at a temperature which is from at least 30° C. to at most 40° C. lower than the temperature of the reaction chamber, or at a temperature which is from at least 40° C. to at most 50° C. lower than the temperature of the reaction chamber. The gas lines may be suitably maintained at a temperature between the temperature of the precursor recipient and the reaction chamber. For example, the gas lines may be maintained at a temperature which is from at least 5° C. to at most 50° C., or from at least 5° C. to at most 10° C., or from at least 10° C. to at most 20° C., or from at least 30° C. to at most 40° C., or from at least 40° C. to at most 50° C. lower than the temperature of the reaction chamber. In some embodiments, the gas lines and the reaction chamber are maintained at a substantially identical temperature which is higher than the temperature of the precursor recipient.

In some embodiments, the gas injection system comprises a precursor delivery system that employs a carrier gas for carrying the precursor to one or more reaction chambers. In some embodiments, continuous flow of carrier gas is accomplished using a flow-pass system. In the flow-pass system, a carrier gas line is provided with a detour line having a precursor reservoir (bottle), and the main line and the detour line are switched, wherein when only a carrier gas is intended to be fed to a reaction chamber, the detour line is closed, whereas when both the carrier gas and the precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line.

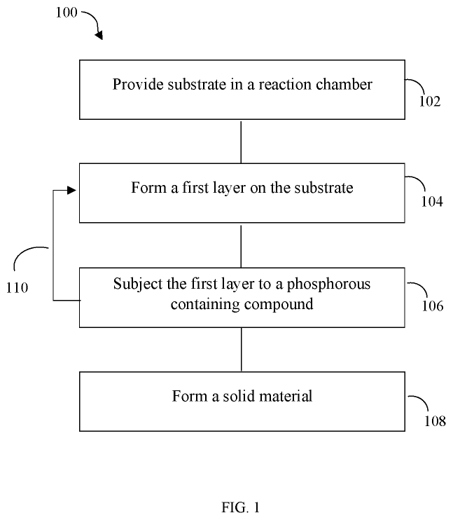

FIG. 1 shows a schematic representation of an embodiment of a method for filling a gap as described herein. The method (100) comprises the step (102) of providing a substrate into a reaction chamber. The substrate comprises at least one gap. Then, the method comprises the step (104) forming a first layer on the substrate. The first layer comprises silicon and nitrogen. In some embodiments, the first layer comprises silicon nitride. The silicon nitride can be deposited by a cyclical deposition process, such as plasma enhanced atomic layer deposition. Other deposition methods may be used, such as atomic layer deposition, chemical vapor deposition or plasma enhanced chemical vapor deposition. In the cyclical deposition process, a silicon precursor is provided into the reaction chamber in a silicon precursor pulse. Then, a plasma pulse is provided. The plasma pulse exposes the substrate to a plasma treatment which comprises generating plasma. The plasma is generated using a plasma gas. In the embodiment where the deposited first layer comprises silicon nitride, the plasma gas comprises nitrogen and optionally one or more noble gas. The plasma can be direct plasma, remote plasma or indirect plasma. In one embodiment, the subsequent deposition cycles are separated by a purge. In another embodiment, the precursor pulse and the plasma pulse at least partially overlap.

Next, the method comprises the step (106) of subjecting the first layer to a phosphorous containing compound to from a flowable intermediate material. In an exemplary embodiment, the phosphorous containing compound comprises phosphoric acid. The phosphoric acid reacts with the formed first layer comprising silicon and nitrogen. The first layer is etched and modified to form a flowable intermediate material, which comprises silicon, hydrogen and oxygen. In one embodiment the flowable intermediate material comprises silicic acid. The flowable intermediate material then flows into the gaps of the substrate and at least partially fills the gaps. The steps (104, 106) of forming the first layer on the substrate and subjecting the first layer to phosphorous containing compound can be repeated (110) sequentially as many times as necessary. The number of cycles can be at least 10 cycles, or at least 50 cycles, or at least 100 cycles, or at least 200 cycles, or at least 400 cycles.

Lastly, the method comprises the step (108) of forming a solid material. Once the flowable intermediate material has at least partially filled the gaps on the substrate, the material condenses and forms a solid material comprising silicon. In one exemplary embodiment, the solid material comprises silicon dioxide.

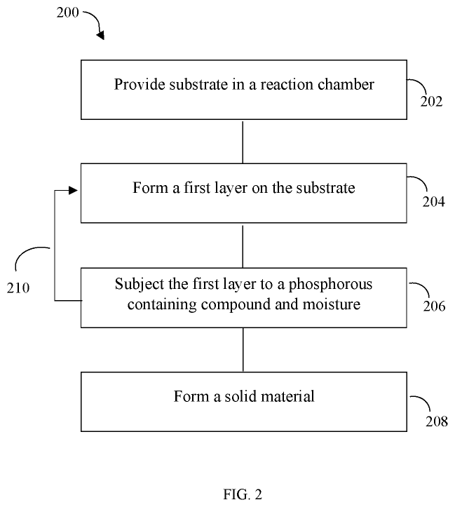

FIG. 2 shows another schematic representation of an embodiment of a method for filling a gap. The method (200) comprises the step (202) of providing a substrate into a reaction chamber. The substrate comprises at least one gap. Then, the method comprises the step (204) forming a first layer on the substrate. The first layer comprises silicon and nitrogen. In some embodiments, the first layer comprises silicon nitride. The silicon nitride can be deposited by a cyclical deposition process, such as plasma enhanced atomic layer deposition. Other deposition methods may be used, such as atomic layer deposition, chemical vapor deposition or plasma enhanced chemical vapor deposition. In the cyclical deposition process, a silicon precursor is provided into the reaction chamber in a silicon precursor pulse. Then, a plasma pulse is provided. The plasma pulse exposes the substrate to a plasma treatment which comprises generating plasma. The plasma is generated using a plasma gas. In the embodiment where the deposited first layer comprises silicon nitride, the plasma gas comprises nitrogen and optionally one or more noble gas. The plasma can be direct plasma, remote plasma or indirect plasma. In one embodiment, the subsequent deposition cycles are separated by a purge. In another embodiment, the precursor pulse and the plasma pulse at least partially overlap.

Next, the method comprises the step (206) of subjecting the first layer to a phosphorous containing compound and moisture to from a flowable intermediate material. In an exemplary embodiment, the phosphorous containing compound comprises trimethyl phosphate. The moisture can be any source of H⁺HO⁻, for example water, steam or hydrogen peroxide. The phosphorous containing compound and moisture can be provided into the reaction chamber as pulses either simultaneously or sequentially. The phosphorous containing compound and moisture pulses may also partially overlap. The phosphorous containing compound reacts with the moisture and further with the surface of the first layer. The cycle containing subjecting the first layer to a phosphorous containing compound and moisture can be performed as many times as necessary. The number of cycles can be at least 10 cycles, or at least 50 cycles, or at least 100 cycles, or at least 200 cycles, or at least 400 cycles. In one exemplary embodiment, the phosphorous containing compound and the moisture form phosphoric acid. The phosphoric acid reacts with the formed first layer comprising silicon and nitrogen. The first layer is etched and modified to form a flowable intermediate material, which comprises silicon, hydrogen and oxygen. In one embodiment the flowable intermediate material comprises silicic acid. The flowable intermediate material then flows into the gaps of the substrate and at least partially fills the gaps. The steps (204, 206) of forming the first layer on the substrate and subjecting the first layer to phosphorous containing compound and moisture can be repeated (210) sequentially as many times as necessary. The number of cycles can be at least 10 cycles, or at least 50 cycles, or at least 100 cycles, or at least 200 cycles, or at least 400 cycles.

Lastly, the method comprises the step (208) of forming a solid material. Once the flowable intermediate material has at least partially filled the gaps on the substrate, the material condenses and forms a solid material comprising silicon. In one exemplary embodiment, the solid material comprises silicon dioxide.

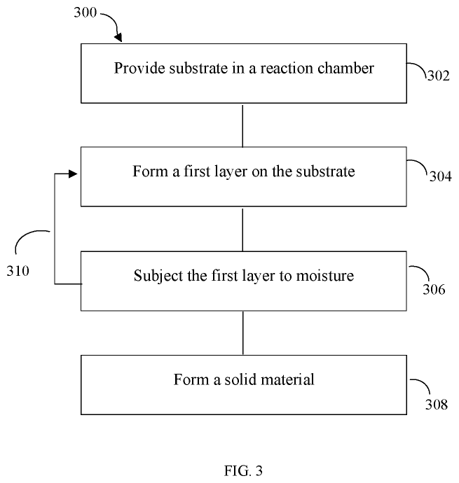

FIG. 3 shows another schematic representation of an embodiment of a method for filling a gap. The method (300) comprises the step (302) of providing a substrate into a reaction chamber. The substrate comprises at least one gap. Then, the method comprises the step (304) forming a first layer on the substrate. The first layer comprises silicon, oxygen, nitrogen and phosphorous. In some embodiments, the first layer comprises SiON:P. The SiON:P can be deposited by a cyclical deposition process, such as plasma enhanced atomic layer deposition. Other deposition methods may be used, such as atomic layer deposition, chemical vapor deposition or plasma enhanced chemical vapor deposition. In the cyclical deposition process as silicon precursor comprising silicon, oxygen and phosphorous is provided into the reaction chamber in a silicon precursor pulse. In one exemplary embodiment the silicon precursor comprises trimethylsilyl phosphite. Then, a plasma pulse is provided. The plasma pulse exposes the substrate to a plasma treatment which comprises generating plasma. The plasma is generated using a plasma gas. In the embodiment where the deposited first layer comprises SiON:P, the plasma gas comprises nitrogen and optionally one or more noble gas. The plasma can be direct plasma, remote plasma or indirect plasma. In one embodiment, the subsequent deposition cycles are separated by a purge. In another embodiment, the precursor pulse and the plasma pulse at least partially overlap.

Next, the method comprises the step (306) of subjecting the first layer to moisture to form a flowable intermediate material. The moisture can be any source of H⁺HO⁻, for example water, steam or hydrogen peroxide. The moisture reacts with the surface of the first layer. In one exemplary embodiment, the phosphorous in the first layer and the moisture form phosphoric acid. The phosphoric acid reacts with the silicon and nitrogen in the first layer. The first layer is then etched and modified to form a flowable intermediate material, which comprises silicon, hydrogen and oxygen. In one embodiment the flowable intermediate material comprises silicic acid. The flowable intermediate material then flows into the gaps of the substrate and at least partially fills the gaps. The steps (304, 306) of forming the first layer on the substrate and subjecting the first layer to moisture can be repeated (310) sequentially as many times as necessary. The number of cycles can be at least 10 cycles, or at least 50 cycles, or at least 100 cycles, or at least 200 cycles, or at least 400 cycles.

Lastly, the method comprises the step (308) of forming a solid material. Once the flowable intermediate material has at least partially filled the gaps on the substrate, the material condenses and forms a solid material comprising silicon. In one exemplary embodiment, the solid material comprises silicon dioxide.

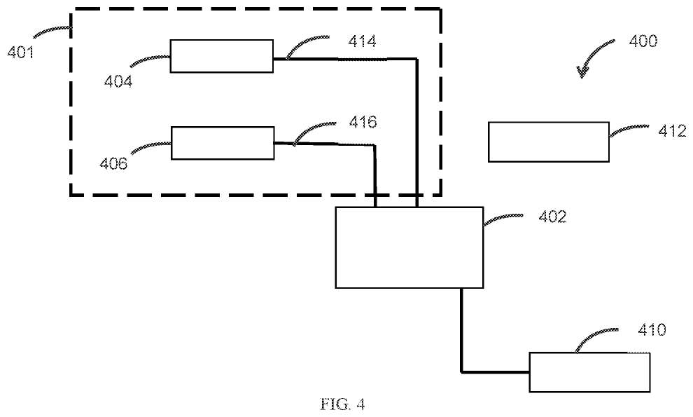

FIG. 4 illustrates a deposition assembly 400 according to the current disclosure in a schematic manner. Deposition assembly 400 can be used to perform a method as described herein and/or to form a structure or a device, or a portion thereof as described herein.

In the illustrated example, deposition assembly 400 includes one or more reaction chambers 402, a precursor injector system 401, a silicon precursor vessel 404, a plasma gas vessel 406, an exhaust source 410, and a controller 412. The deposition assembly 400 may comprise one or more additional gas sources (not shown), such as an inert gas source, a carrier gas source and/or a purge gas source.

Reaction chamber 402 can include any suitable reaction chamber, such as an ALD or CVD reaction chamber as described herein.

The silicon precursor vessel 404 can include a vessel and one or more silicon precursors as described herein-alone or mixed with one or more carrier (e.g., inert) gases. A plasma gas vessel 406 can include a vessel and a plasma gas as described herein-alone or mixed with one or more carrier gases. Although illustrated with two source vessels 404, 406, deposition assembly 400 can include any suitable number of source vessels. Source vessels 404, 406 can be coupled to reaction chamber 402 via lines 414, 416, which can each include flow controllers, valves, heaters, and the like. In some embodiments, the silicon precursor in the silicon precursor vessel 404 and the plasma gas in the plasma gas vessel 406 may be heated. In some embodiments, a vessel is heated so that a precursor or a reactant reaches a temperature between, for example, about 30° C. and about 200° C., depending on the properties of the chemical in question.

Exhaust source 410 can include one or more vacuum pumps.

Controller 412 includes electronic circuitry and software to selectively operate valves, manifolds, heaters, pumps and other components included in the deposition assembly 400. Such circuitry and components operate to introduce precursors, reactants and purge gases from the respective sources. Controller 412 can control timing of gas pulse sequences, temperature of the substrate and/or reaction chamber 402, pressure within the reaction chamber 402, and various other operations to provide proper operation of the deposition assembly 400. Controller 412 can include control software to electrically or pneumatically control valves to control flow of precursors, reactants and purge gases into and out of the reaction chamber 402. Controller 412 can include modules such as a software or hardware component, which performs certain tasks. A module may be configured to reside on the addressable storage medium of the control system and be configured to execute one or more processes.

Other configurations of deposition assembly 400 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 402. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 400, substrates, such as semiconductor wafers (not illustrated), are transferred from, e.g., a substrate handling system to reaction chamber 402. Once substrate(s) are transferred to reaction chamber 402, one or more gases from gas sources, such as precursors, reactants, carrier gases, and/or purge gases, are introduced into reaction chamber 402.

In some embodiments, the silicon precursor is supplied in pulses, the plasma gas is supplied in pulses and the reaction chamber is purged between consecutive pulses of a silicon precursor and a plasma gas.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for filling a gap in a substrate, the method comprising
providing a substrate into a reaction chamber, wherein the substrate comprises at least one gap;
forming a first layer on a substrate, wherein the first layer comprises silicon and nitrogen;
subjecting the first layer to a phosphorous-containing compound to form a flowable intermediate material at least partially filling the at least one gap on the substrate, wherein the intermediate material comprises silicon, oxygen and hydrogen; and
forming a solid material comprising silicon.

2. The method according to claim 1, wherein the step of subjecting the first layer to a phosphorous-containing compound additionally comprises subjecting the first layer to moisture.

3. The method according to claim 2, wherein the moisture is selected from the group consisting of H₂O, steam, and H₂O₂.

4. The method according to claim 1, wherein the solid material comprises silicon dioxide.

5. The method according to claim 1, wherein the phosphorous-containing compound comprises phosphorous at an amount so that first layer comprises at least 4 atomic-% phosphorous after it has been subjected to the phosphorous containing compound.

6. The method according to claim 1, wherein the step of forming a first layer comprises executing a plurality of deposition cycles to form a silicon-containing layer, at least one deposition cycle comprising:
a silicon precursor pulse that comprises exposing the substrate to a silicon precursor; and
a plasma pulse that comprises exposing the substrate to a plasma treatment, wherein the plasma treatment comprises generating plasma.

7. The method according to claim 6, wherein the plasma is a direct plasma.

8. The method according to claim 6, wherein the plasma is a remote plasma.

9. The method according to claim 6, wherein the plasma is an indirect plasma.

10. The method according to claim 6, wherein the plasma is generated using plasma gas, the plasma gas comprising N₂ and optionally one or more noble gas.

11. The method according to claim 10, wherein the noble gas comprises one or more of He and Ar.

12. The method according to claim 6, wherein the silicon precursor comprises silicon and optionally phosphorous.

13. The method according to claim 6, wherein subsequent deposition cycles are separated by a purge.

14. The method according to claim 6, wherein the silicon precursor pulse and the plasma pulse at least partially overlap.

15. The method according to claim 1, wherein the method comprises one or more super cycles, a super cycle comprising the step of forming the first layer on a substrate, subjecting the first layer to the phosphorous-containing compound and forming a solid material comprising silicon.

16. The method according to claim 1, further comprising an anneal step, wherein the solid material is exposed to heating to a temperature between 500° C. and 700° C.

17. The method according to claim 6, wherein the forming the first layer further comprises a second plasma pulse that comprises exposing the substrate to a second plasma treatment, and wherein the second plasma treatment comprises generating plasma.

18. The method according to claim 17, wherein the second plasma is generated using plasma gas, the plasma gas comprising a gas selected from the group consisting of NH₃, H₂, a mixture of H₂ and N₂, a mixture of H₂ and He, and a mixture of H₂, argon, and N₂H₂.

19. The method according to claim 1, wherein, before the forming a first layer on a substrate, a liner layer is deposited into the gap.

20. A semiconductor processing apparatus comprising:
a reaction chamber comprising a substrate support for supporting a substrate;
a heater constructed and arranged to heat the substrate in the reaction chamber;
a plasma module comprising a radio frequency power source constructed and arranged to generate a plasma;
a plasma gas source in fluid communication with the plasma module;
a silicon precursor source in fluid connection with the reaction chamber via one or more precursor valves; and
a controller configured for causing the semiconductor processing apparatus to perform a method according to claim 1.
